(19) United States
(12) Patent Application Publication
(10) Pub. No.: US 2024/0184464 A1
(43) Pub. Date: Jun. 6, 2024

(54) METHOD FOR OPERATING MEMORY DEVICE AND MEMORY DEVICE

(71) Applicant: MACRONIX INTERNATIONAL CO., LTD., Hsinchu (TW)

(72) Inventors: Yu-Hsuan LIN, Taichung City (TW); Hsiang-Lan LUNG, Kaohsiung City (TW); Cheng-Lin SUNG, Hsinchu County (TW)

(21) Appl. No.: 18/302,942

(22) Filed: Apr. 19, 2023

Related U.S. Application Data
(60) Provisional application No. 63/430,653, filed on Dec. 6, 2022.

(51) Int. Cl. G06F 3/06

(52) U.S. Cl. CPC G06F 3/0632; G06F 3/0604; G06F 3/0679

(57) ABSTRACT

A method for operating a memory device is provided. The method includes following steps. First, a priority of a refresh operation and a priority of an inference operation for at least a portion of a memory array of the memory device are determined. The refresh operation and the inference operation are performed according to a determination result of the priority of the refresh operation and the priority of the inference operation. If the priority of the refresh operation is lower than the priority of inference operation, perform the inference operation in the at least a portion, and perform the refresh operation after performing the inference operation. If the priority of the refresh operation is higher than the priority of inference operation, perform the refresh operation in the at least a portion, and perform the inference operation after performing the refresh operation.

This application claims the benefit of U.S. provisional application Ser. No. 63/430,653, filed Dec. 6, 2022, the subject matter of which is incorporated herein by reference.

### TECHNICAL FIELD

This disclosure relates to a method for operating a memory device and a memory device. More particularly, this disclosure relates to a method for operating a memory device able to perform an inference operation and a memory device able to perform an inference operation.

### BACKGROUND

With the rapid development of artificial intelligence (AI) algorithm in various fields of applications such as automobile, consumer, military market, and so on, the computing performance is no longer dominated solely by optimizing AI software, but the natural bottleneck of hardware accelerators should be overcome. To improve data traffic between a memory bus and a processing unit, in-memory computing is a promising alternative. However, current memory devices have some drawbacks, including read disturb, retention loss, drift, and endurance issues. In order to prevent degrade of AI inference operation, data loss should be avoided. Data refresh is typical technical means to compensate data loss, and should be done before inference accuracy degrades. However, the insertion of refresh operation between basic operations of AI algorithm may lead to additional time consumption and reduce the computing performance for AI inference operation. For example, it takes almost 20 seconds to refresh the 19 layers of weights in a VGG19 architecture.

### SUMMARY

This disclosure provides a method for operating a memory device and a memory device for operating the same to address the time consuming and computing performance reducing issues.

In one aspect of the disclosure, a method for operating a memory device is provided. The method comprises following steps. First, a priority of a refresh operation and a priority of an inference operation for at least a portion of a memory array of the memory device are determined. The refresh operation and the inference operation are performed according to a determination result of the priority of the refresh operation and the priority of the inference operation. If the priority of the refresh operation is lower than the priority of inference operation, perform the inference operation in the at least a portion, and perform the refresh operation after performing the inference operation. If the priority of the refresh operation is higher than the priority of inference operation, perform the refresh operation in the at least a portion, and perform the inference operation after performing the refresh operation.

In another aspect of the disclosure, a memory device is provided. The memory device comprises a memory array. The memory array is configured so that at least a portion of the memory array performs a refresh operation and an inference operation according to a determination result of a priority of the refresh operation and a priority of the inference operation, wherein if the priority of the refresh operation is lower than the priority of inference operation, the refresh operation is performed after the inference operation, and wherein if the priority of the refresh operation is higher than the priority of inference operation, the refresh operation is performed before the inference operation.

### BRIEF DESCRIPTION OF THE DRAWINGS

FIG. 1 illustrates a flow diagram of a method for operating a memory device according to the disclosure.

FIG. 2 illustrates a memory device according to the disclosure.

FIGS. 3A-3C illustrate an exemplary condition of the method according to the disclosure.

FIGS. 4A-4C illustrate another exemplary condition of the method according to the disclosure.

FIGS. 5A-5C illustrate still another exemplary condition of the method according to the disclosure.

FIG. 6 illustrates an example the memory device according to the disclosure.

FIG. 7 illustrates another example the memory device according to the disclosure.

FIGS. 8A-8B illustrate various sequence followed by refresh operations.

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

### DETAILED DESCRIPTION

Various embodiments will be described more fully hereinafter with reference to accompanying drawings. The description and the drawings are provided for illustrative only, and not intended to result in a limitation. For clarity, the elements may not be drawn to scale. In addition, some elements and/or reference numerals may be omitted from some drawings. It is contemplated that the elements and features of one embodiment can be beneficially incorporated in another embodiment without further recitation.

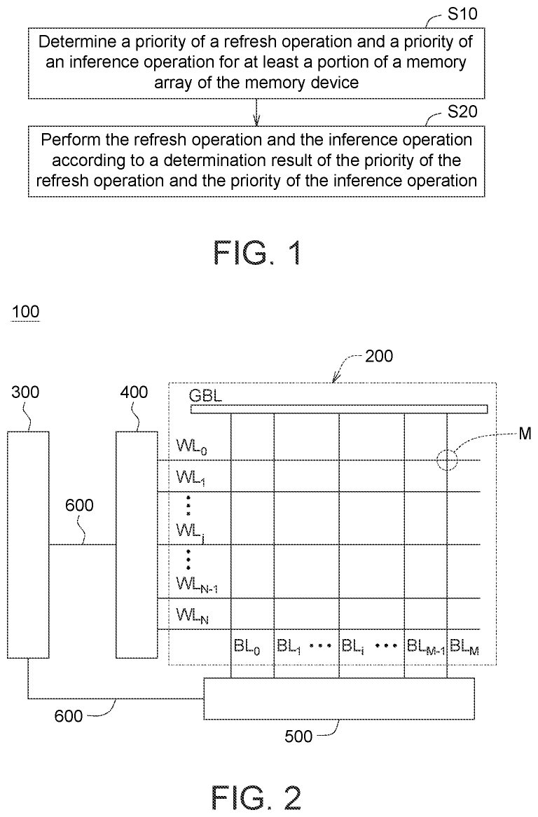

In this disclosure, a method for operating a memory device is provided. Referring to FIG. 1, a flow diagram of the method according to the disclosure is shown. In a step S10, a priority of a refresh operation and a priority of an inference operation for at least a portion of a memory array of the memory device are determined. In a step S20, the refresh operation and the inference operation are performed according to a determination result of the priority of the refresh operation and the priority of the inference operation. If the priority of the refresh operation is lower than the priority of inference operation, perform the inference operation in the at least a portion, and perform the refresh operation after performing the inference operation. If the priority of the refresh operation is higher than the priority of inference operation, perform the refresh operation in the at least a portion, and perform the inference operation after performing the refresh operation.

FIG. 2 shows a memory device 100 able to operate the method. The memory device 100 comprises a memory array 200. The memory array 200 comprises a plurality of memory cells M defined by cross points of bit lines and word lines. In the accompanying drawings, a global bit line GBL and several bit lines BL₀, BL₁, BLᵢ, BL_{M-1}, and BL_{M} and word lines WL₀, WL₁, WLⱼ, WL_{N-1}, and WL_{N} are exemplarily shown, and the other signal lines for the memory array 200 (for example, the bit lines BL₂ to BLᵢ₋₁ and BLᵢ₊₁ to BL_{M-2} and the word lines WL₂ to WLⱼ₋₁ and WLⱼ₊₁ to WL_{N-2}) are omitted for clarity of the drawings. It is understood that a total number of the bit lines can be different from a total number of the word lines. The memory device 100 can further comprise a memory controller 300 for controlling operations of the memory array 200. The memory device 100 can further comprise a word line driver 400 coupled to the word lines WL₀ to WL_{N} and a bit line driver 500 coupled to the bit lines BL₀ to BL_{M}. The memory controller 300 is coupled to the word line driver 400 and the bit line driver 500 through signal lines 600, and thus further coupled to the word lines WL₀ to WL_{N} and the bit lines BL₀ to BL_{M} to control the memory array 200. In order to clearly illustrate the method according to the disclosure, the following details will be described in conjunction with the memory device 100, and particular with the memory array 200.

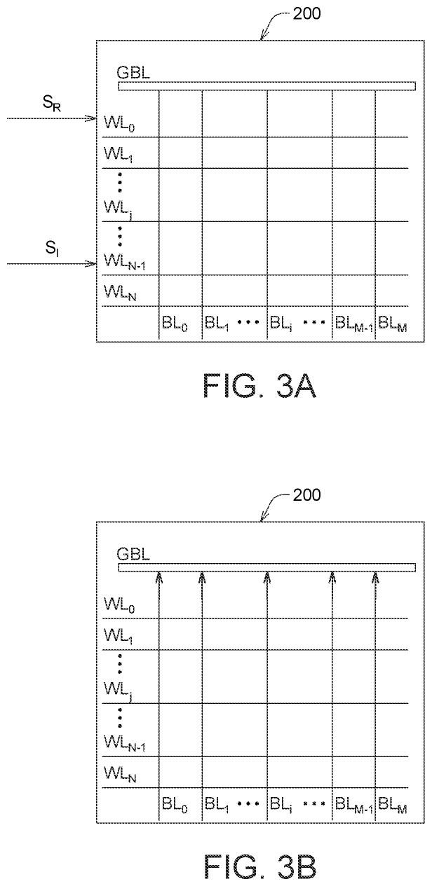

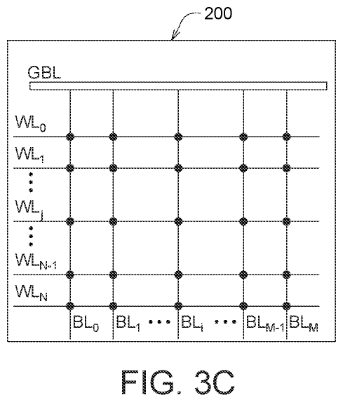

FIGS. 3A-3C illustrate an exemplary condition of the method according to the disclosure. The step S10, i.e., determining the priority of the refresh operation and the priority of the inference operation for the at least a portion of the memory array 200, can be performed when a refresh signal SR and an inference signal Si are simultaneously transmitted to the at least a portion of the memory array 200. As shown in FIG. 3A, the refresh signal SR and an inference signal Si are simultaneously transmitted to the memory array 200, and thus a conflict happens. According to some embodiments, determining the priority of the refresh operation and the priority of the inference operation for the at least a portion of the memory array 200 can be performed based on one or more instructions from the memory controller 300. The one or more instructions can be pre-written into and stored in the memory controller 300. The priorities can be determined according to memory characteristics. However, the disclosure is not limited thereto. In this exemplary condition, the priority of the refresh operation is lower than the priority of inference operation for the whole memory array 200. Accordingly, the inference operation is first performed in the whole memory array 200, as shown in FIG. 3B. In the accompanying drawings, the inference operation is indicated by arrows from the bit lines BL₀ to BL_{M} to the global bit line GBL, which represent a multiply-and-accumulate (MAC) calculation typically used for the inference operation. It is understood that the inference operation is not limited thereto, and any suitable means can be performed for the inference operation of the disclosure. Then, the refresh operation is performed in the whole memory array 200, as shown in FIG. 3C. In the accompanying drawings, the refresh operation is indicated by solid dots on corresponding memory cells M.

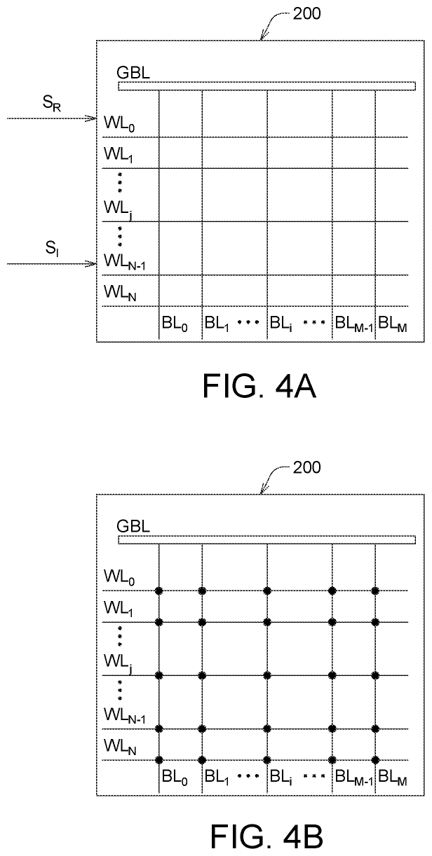

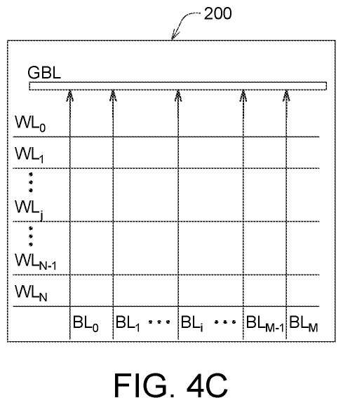

FIGS. 4A-4C illustrate another exemplary condition of the method according to the disclosure. As shown in FIG. 4A, a refresh signal SR and an inference signal Si are simultaneously transmitted to the memory array 200. In this exemplary condition, the priority of the refresh operation is higher than the priority of inference operation for the whole memory array 200. Accordingly, the refresh operation is first performed in the whole memory array 200, as shown in FIG. 4B. Then, the inference operation is performed in the whole memory array 200, as shown in FIG. 4C.

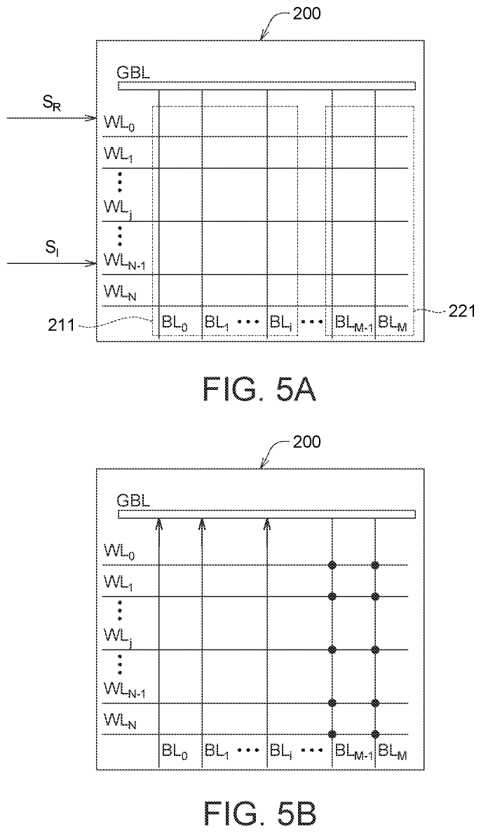

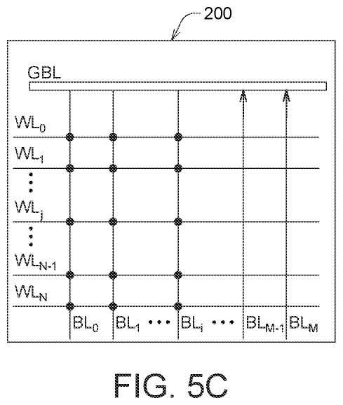

FIGS. 5A-5C illustrate still another exemplary condition of the method according to the disclosure. As shown in FIG. 5A, a refresh signal SR and an inference signal Si are simultaneously transmitted to the memory array 200. In this exemplary condition, the memory array 200 comprises a first portion, the portion 211, and a second portion, the portion 221, wherein for the first portion, the priority of the refresh operation is lower than the priority of inference operation, and wherein for the second portion, the priority of the refresh operation is higher than the priority of inference operation. As shown in FIG. 5B, for the portion 211, the inference operation is first performed, and for the portion 221, the refresh operation is first performed. Then, as shown in FIG. 5C, for the portion 211, the refresh operation is performed, and for the portion 221, the inference operation is performed.

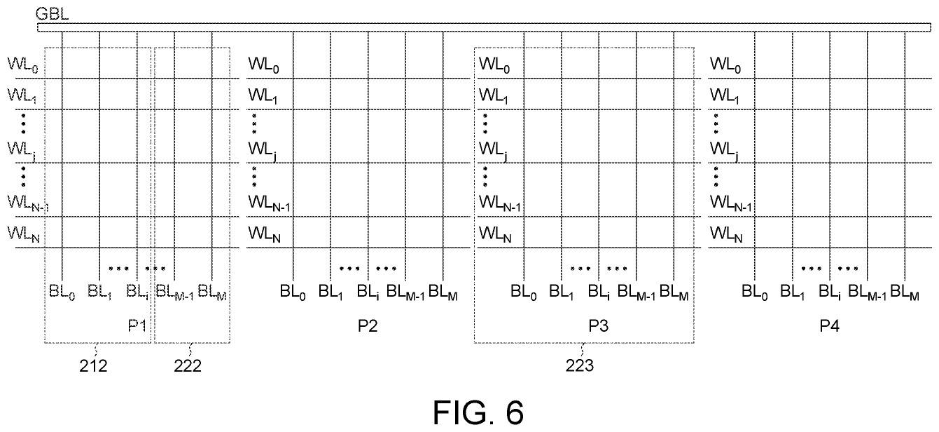

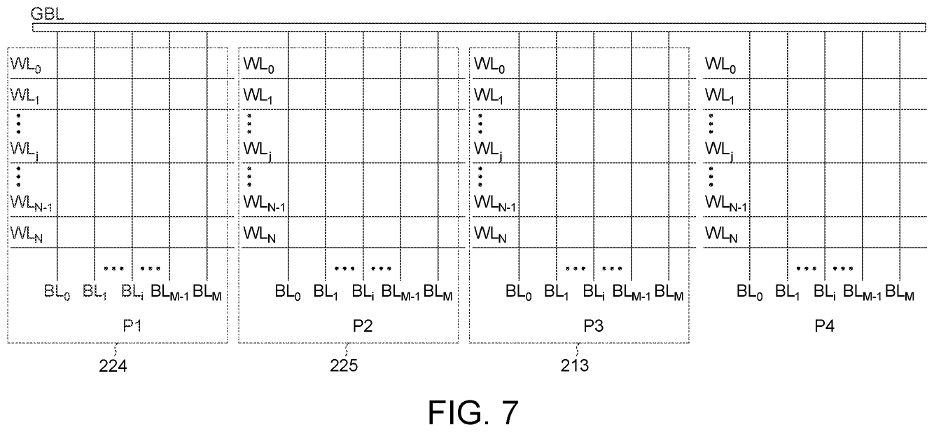

The first portion of the memory array 200, for which the priority of the refresh operation is lower than the priority of inference operation, can be one or more parts of cells in one or more page, one or more pages, one or more blocks, or any combinations thereof. Similarly, the second portion of the memory array 200, for which the priority of the refresh operation is higher than the priority of inference operation, can be one or more parts of cells in one or more page, one or more pages, one or more blocks, or any combinations thereof. For example, the first portion and the second portion each can be a part of cells in a page, a whole page, several pages, a single block, several blocks, or the like. FIG. 6 shows a specific example that the memory array 200 comprises the two kinds of portions. In the accompanying drawings, four pages P1 to P4 of the memory array 200 are exemplarily shown. In the example as shown in FIG. 6, the first portion of the memory array 200 comprises the portion 212, and the second portion of the memory array 200 comprises the portions 222 and 223. The portion 212 is a part of cells in the page P1. The portion 222 is another part of cells in the page P1. The portion 223 is the whole page P3. FIG. 7 shows another specific example that the memory array 200 comprises the two kinds of portions. In the example as shown in FIG. 7, the first portion of the memory array 200 comprises the portion 213, and the second portion of the memory array 200 comprises the portions 224 and 225. The portion 213 is the page P3. The portion 224 is the page P1. The portion 225 is the page P2. In some embodiments, as the page P1 shown in FIG. 6, part of cells in one page of the memory array 200 can belong to the first portion, and another part of cells in the page can belong to the second portion. In some further embodiments, part of cells in one page of the memory array 200 can belong to the first portion, and the other part of cells in the page can belong to the second portion.

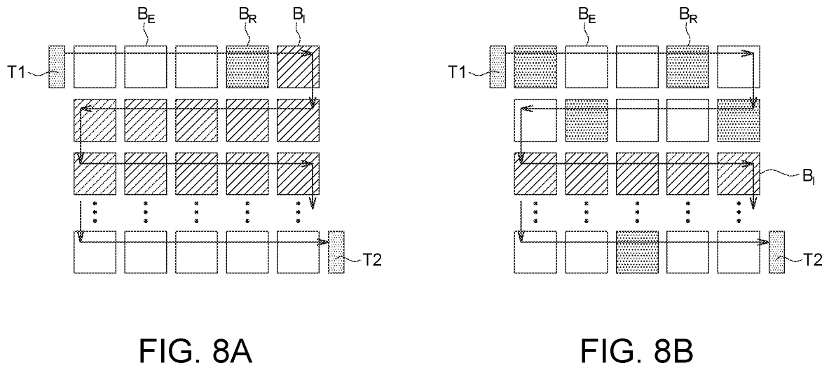

Referring back to FIG. 1, in the step S20, the refresh operation can comprise reading out data from the at least a portion and rewriting the read data into the at least a portion. The data may be resistances representing weights for AI algorithm. However, the disclosure is not limited thereto. The refresh operation can be performed simultaneously in one or more parts of cells in one or more page, one or more pages, one or more blocks, or any combinations thereof. The refresh operation can follow a data flow sequence, a designated sequence, or a random sequence. For example, FIG. 8A shows the condition that the refresh operation follows a data flow sequence, in which arrows indicate the directions of data flow from an input terminal T1 to an output terminal T2, blank blocks B_{E} are standby blocks, a single dotted block B_{R} is a refresh block, and slash blocks B_{I} are inference blocks. FIG. 8B show the condition that the refresh operation follows an exemplary designated sequence, in which arrows indicate the directions of data flow from an input terminal T1 to an output terminal T2, blank blocks B_{E} are standby blocks, multiple dotted blocks B_{R} are refresh blocks, and slash blocks B_{I} are inference blocks.

The inference operation can comprise a multiply-and-accumulate calculation, which is an application of in-memory computing (IMC). Additionally or alternatively, the inference operation can comprise comparing data and input, which is an application of in-memory search (IMS). However, it is understood that the inference operation of the disclosure is not limited thereto, and any suitable means can be performed.

Now the disclosure is directed to a memory device. Referring to FIG. 2, a memory device 100 according to the disclosure comprises a memory array 200. The memory array 200 is configured so that at least a portion of the memory array 200 performs a refresh operation and an inference operation according to a determination result of a priority of the refresh operation and a priority of the inference operation, wherein if the priority of the refresh operation is lower than the priority of inference operation, the refresh operation is performed after the inference operation, and wherein if the priority of the refresh operation is higher than the priority of inference operation, the refresh operation is performed before the inference operation.

In some embodiments, as shown in FIGS. 3A-3C to FIG. 7, the memory array 200 comprises a first portion and a second portion, the first portion is configured so that a priority of the refresh operation is lower than a priority of inference operation, and the second portion is configured so that a priority of the refresh operation is higher than a priority of inference operation. The first portion of the memory array can be one or more parts of cells in one or more page, one or more pages, one or more blocks, or any combinations thereof. The second portion of the memory array can be one or more parts of cells in one or more page, one or more pages, one or more blocks, or any combinations thereof. In some embodiments, part of cells in one page of the memory array belongs to the first portion, and another part of cells in the page belongs to the second portion, as the page P1 shown in FIG. 6. In some embodiments, part of cells in one page of the memory array belongs to the first portion, and the other part of cells in the page belongs to the second portion.

The memory device 100 can further comprise a global bit line GBL, a plurality of bit lines BL₀ to BL_{M}, a plurality of word lines WL₀ to WL_{N}, and other suitable elements for the memory array 200. A plurality of memory cells M of the memory array 200 can be defined by cross points of the bit lines BL₀ to BL_{M} and the word lines WL₀ to WL_{N}.

The memory device 100 can further comprise a memory controller 300 coupled to the memory array 200. The memory controller 300 is configured to control operations of the memory array 200. For example, the memory controller 300 can have one or more instructions determining the priority of the refresh operation and the priority of the inference operation for the at least a portion of the memory array 200.

The memory device 100 can further comprise a word line driver 400 coupled to the word lines WL₀ to WL_{N}, a bit line driver 500 coupled to the bit lines BL₀ to BL_{M}, and signal lines 600. As such, the memory controller 300 can be coupled to the word line driver 400 and the bit line driver 500 through the signal lines 600, and thus further coupled to the word lines WL₀ to WL_{N} and the bit lines BL₀ to BL_{M} to control the memory array 200.

According to some embodiments, the memory device 100 can be a nonvolatile memory, such as a phase change memory (PCM), a resistive random access memory (ReRAM), a ferroelectric random access memory (FeRAM), a ferroelectric field effect transistor (FeFET) memory, a magnetoresistive random access memory (MRAM), a flash memory, or the like.

In summary, the disclosure provides a method for operating a memory device and a memory device for operating the same. In the disclosure, a refresh operation and an inference operation are performed according to their priorities, especially when a conflict happens between a refresh signal and an inference signal. As such, the time consuming and computing performance reducing issues caused by the data refresh before the inference operation can be mitigated. Further, the effect of the memory reliability problems may be eliminated.

It will be apparent to those skilled in the art that various modifications and variations can be made to the disclosed embodiments. It is intended that the specification and examples be considered as exemplary only, with a true scope of the disclosure being indicated by the following claims and their equivalents.

What is claimed is:

1. A method for operating a memory device, comprising:
determining a priority of a refresh operation and a priority of an inference operation for at least a portion of a memory array of the memory device; and
performing the refresh operation and the inference operation according to a determination result of the priority of the refresh operation and the priority of the inference operation, wherein
if the priority of the refresh operation is lower than the priority of inference operation, performing the inference operation in the at least a portion, and performing the refresh operation after performing the inference operation, and
if the priority of the refresh operation is higher than the priority of inference operation, performing the refresh operation in the at least a portion, and performing the inference operation after performing the refresh operation.

2. The method according to claim 1, wherein determining the priority of the refresh operation and the priority of the inference operation for the at least a portion of the memory array is performed when a refresh signal and an inference signal are simultaneously transmitted to the at least a portion.

3. The method according to claim 1, wherein determining the priority of the refresh operation and the priority of the inference operation for the at least a portion of the memory array is performed based on one or more instructions from a memory controller.

4. The method according to claim 3, wherein the one or more instructions are pre-written into and stored in the memory controller.

5. The method according to claim 1, wherein the memory array comprises a first portion and a second portion, wherein for the first portion, the priority of the refresh operation is lower than the priority of inference operation, and wherein for the second portion, the priority of the refresh operation is higher than the priority of inference operation.

6. The method according to claim 5, wherein the first portion of the memory array is one or more parts of cells in one or more page, one or more pages, one or more blocks, or any combinations thereof.

7. The method according to claim 5, wherein the second portion of the memory array is one or more parts of cells in one or more page, one or more pages, one or more blocks, or any combinations thereof.

8. The method according to claim 5, wherein part of cells in one page of the memory array belongs to the first portion, and another part of cells in the page belongs to the second portion.

9. The method according to claim 5, wherein part of cells in one page of the memory array belongs to the first portion, and the other part of cells in the page belongs to the second portion.

10. The method according to claim 1, wherein the refresh operation is performed simultaneously in one or more parts of cells in one or more page, one or more pages, one or more blocks, or any combinations thereof.

11. The method according to claim 1, wherein the refresh operation follows a data flow sequence, a designated sequence, or a random sequence.

12. The method according to claim 1, wherein the inference operation comprises a multiply-and-accumulate calculation, or the inference operation comprises comparing data and input.

13. A memory device, comprising:
a memory array configured so that at least a portion of the memory array performs a refresh operation and an inference operation according to a determination result of a priority of the refresh operation and a priority of the inference operation, wherein if the priority of the refresh operation is lower than the priority of inference operation, the refresh operation is performed after the inference operation, and wherein if the priority of the refresh operation is higher than the priority of inference operation, the refresh operation is performed before the inference operation.

14. The memory device according to claim 13, wherein the memory array comprises a first portion and a second portion, the first portion is configured so that a priority of the refresh operation is lower than a priority of inference operation, and the second portion is configured so that a priority of the refresh operation is higher than a priority of inference operation.

15. The memory device according to claim 14, wherein the first portion of the memory array is one or more parts of cells in one or more page, one or more pages, one or more blocks, or any combinations thereof.

16. The memory device according to claim 14, wherein the second portion of the memory array is one or more parts of cells in one or more page, one or more pages, one or more blocks, or any combinations thereof.

17. The memory device according to claim 14, wherein part of cells in one page of the memory array belongs to the first portion, and another part of cells in the page belongs to the second portion.

18. The memory device according to claim 14, wherein part of cells in one page of the memory array belongs to the first portion, and the other part of cells in the page belongs to the second portion.

19. The memory device according to claim 13, further comprising:
a memory controller coupled to the memory array, the memory controller configured to control operations of the memory array.

20. The memory device according to claim 19, wherein the memory controller has one or more instructions determining the priority of the refresh operation and the priority of the inference operation for the at least a portion of the memory array.
